(19) United States
(12) Patent Application Publication
(10) Pub. No.: US 2023/0203210 A1
(43) Pub. Date: Jun. 29, 2023

(54) PHOTOCURABLE COMPOSITION WITH ENHANCED THERMAL STABILITY

(71) Applicant: CANON KABUSHIKI KAISHA, Tokyo (JP)

(72) Inventors: Fen WAN, Austin, TX (US); Weijun LIU, Cedar Park, TX (US)

(21) Appl. No.: 17/646,108

(22) Filed: Dec. 27, 2021

(51) Int. Cl. C08F 2/48; C08F 12/32; C08F 16/22; C08F 220/18; C09D 11/101; C09D 11/30; G03F 7/028; B41M 5/00

(52) U.S. Cl. CPC C08F 2/48; C08F 12/32; C08F 16/22; C08F 220/18; C09D 11/101; C09D 11/30; G03F 7/028; B41M 5/0023

(57) ABSTRACT

A photocurable composition can comprise a polymerizable material and a photoinitiator, wherein the polymerizable material can comprise a first polymerizable monomer having a structure of Formula (1) or Formula (2):

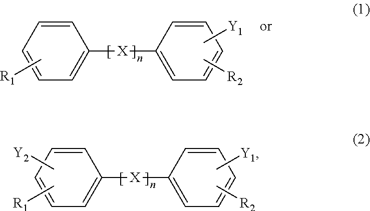

with
X being C₁-C₄-alkyl or oxygen (O); n being 0 or 1
Y₁, Y₂ being

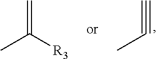

with R₃ or, with R₃ being H or methyl, wherein Y₁ and Y₂ may be the same or different and an amount of Y₁ and Y₂ per benzene ring being 1, 2, or 3;
R₁, R₂ being substituted or unsubstituted alkyl or aryl, and an amount of each of R₁ and R₂ per benzene ring being 0, 1, 2, 3, or 4.

### FIELD OF THE DISCLOSURE

The present disclosure relates to a photocurable composition, particularly to a photo-curable composition for inkjet adaptive planarization adapted for forming photo-cured layers.

### BACKGROUND

Inkjet Adaptive Planarization (IAP) is a process which planarizes a surface of a substrate, e.g., a wafer containing an electric circuit, by jetting liquid drops of a photocurable composition on the surface of the substrate and bringing a flat superstrate in direct contact with the added liquid to form a flat liquid layer. The flat liquid layer is typically solidified under UV light exposure and after removal of the superstrate a planar polymeric surface is obtained, which can be subjected to subsequent processing steps, for example, baking, etching, and/or further deposition steps.

There exists a need for improved IAP materials leading to planar photo-cured layers with high etch resistance and good thermal stability during subsequent processing.

### SUMMARY

In one embodiment, a photocurable composition can comprise a photoinitiator and a polymerizable material, wherein the polymerizable material may comprise a first polymerizable monomer having a structure of formula (1) or formula (2):

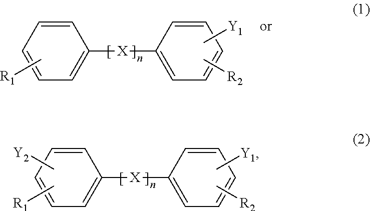

with X being C₁-C₄-alkyl or oxygen (O); n being 0 or 1; Y₁, Y₂

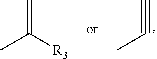

being R₃ or, with R₃ being H or methyl, wherein Y₁ and Y₂ may be the same or different and an amount of Y₁ and Y₂ per benzene ring being 1, 2, or 3; R₁, R₂ being substituted or unsubstituted alkyl or aryl, and an amount of each of R₁ and R₂ per benzene ring being 0, 1, 2, 3, or 4.

In a certain embodiment, the first polymerizable monomer of the photocurable composition can include a structure selected from formula (3), (4), (5), or (6):

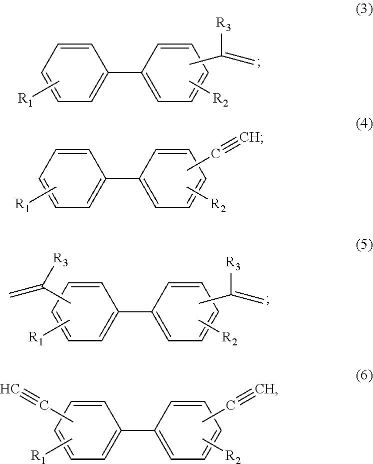

wherein R₃ is H or methyl, R₁ and R₂ are one or more alkyl, aryl, or alkyl aryl and may be the same or different, an amount of each of R₁ and R₂ per benzene ring being 0, 1, 2, 3, or 4, an amount of

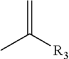

per benzene ring being 1 or 2, and an amount of or

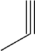

per benzene ring being 1 or 2.

In another embodiment, the first polymerizable monomer of the polymerizable material can include a structure selected from formula (7), (8), (9), or (10):

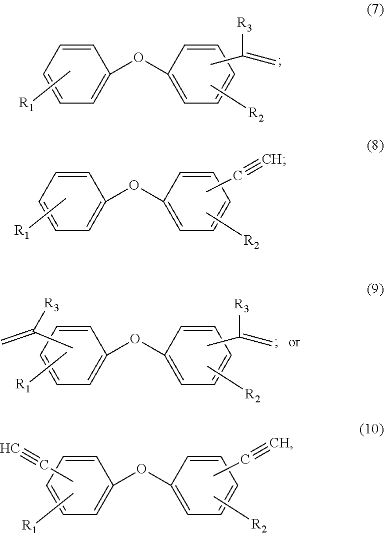

wherein R₃ is H or methyl, and R₁ and R₂ are one or more alkyl, aryl, or alkyl aryl and may be the same or different, an amount of each of R₁ and R₂ per benzene ring being 0, 1, 2, 3, or 4, an amount of

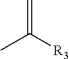

per benzene ring being 1 or 2, and an amount of or

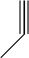

per benzene ring being 1 or 2.

In certain aspects of the photocurable composition, the first polymerizable monomer can be at least one monomer selected from the following structures:

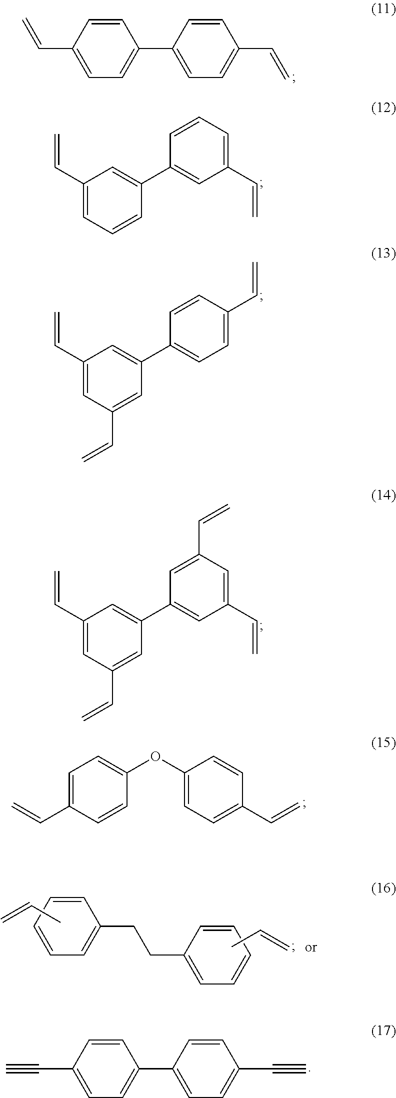

In another aspect, the polymerizable material can comprise at least one second monomer, the at least one second monomer including at least one acrylate monomer. In a particular aspect, the at least one acrylate monomer of the second monomer may include at least two multi-functional acrylate monomers. In a certain particular aspect, the at least one acrylate monomer can comprise at least one mono-functional acrylate monomer and at least one multi-functional acrylate monomer.

In an embodiment, the amount of the polymerizable material of the photocurable composition can be at least 80 wt % based on the total weight of the photocurable composition.

In another embodiment, the viscosity at 23° C. of the photocurable composition may be not greater than 50 mPa s.

In a certain aspect, the photocurable composition can comprise a solvent in an amount of at least 15 vol % based on the total volume of the photocurable composition.

In another certain aspect, the photocurable composition can be essentially free of a solvent.

In a further aspect of the photocurable composition, the amount of the first monomer can be at least 5 wt % and not greater than 90 wt % based on the total weight of the photocurable composition. In a particular aspect, the amount of the first monomer can be at least 30 wt % based on the total weight of the polymerizable material.

In one aspect, the photocurable composition can be adapted for use in inkjet adaptive planarization (IAP) or nanoimprint lithography (NIL).

In another embodiment, a laminate can comprise a substrate and a photo-cured layer overlying the substrate, wherein the photo-cured layer can be formed from the above-described photocurable composition of the present disclosure.

In one aspect, the photo-cured layer of the laminate can have a carbon content of at least 70%.

In another aspect of the laminate, the photo-cured layer can have a thermal stability of at least 250° C.

In one embodiment, a method of forming a photo-cured layer on a substrate can comprise: applying a layer of a photocurable composition on the substrate, wherein the photocurable composition comprises a photoinitiator and a polymerizable material, the polymerizable material including a first polymerizable monomer having a structure of Formula (1) or Formula (2):

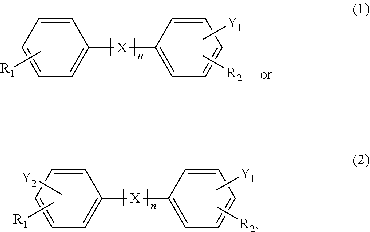

with X being C₁-C4-alkyl or oxygen (O); n being 0 or 1; Y₁, Y₂ being

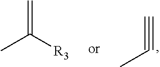

with R₃ being H or methyl, wherein Y₁ and Y₂ may be the same or different and an amount of Y₁ and Y₂ per benzene ring being 1, 2, or 3; R₁, R₂ being substituted or unsubstituted alkyl or aryl, and an amount of each of R₁ and R₂ per benzene ring being 0, 1, 2, 3, or 4; bringing the photocurable composition into contact with a template or a superstrate; irradiating the photocurable composition with light to form a photo-cured layer; and removing the template or the superstrate from the photo-cured layer.

In one aspect of the method, the first polymerizable monomer can comprise at least one second monomer, wherein the at least one second monomer may include at least one acrylate monomer.

In another embodiment, a method of forming an article can comprise: applying a layer of the above-described photocurable composition on the substrate; bringing the photocurable composition into contact with a template or a superstrate; irradiating the curable composition with light to form a cured layer; removing the template or the superstrate from the photo-cured layer; forming a pattern on the substrate; processing the substrate on which the pattern has been formed in the forming; and manufacturing an article from the substrate processed in the processing.

### BRIEF DESCRIPTION OF THE DRAWINGS

Embodiments are illustrated by way of example and are not limited in the accompanying figures.

FIG. 1 includes a graph illustrating TGA curves of photo-cured materials according to embodiments.

### DETAILED DESCRIPTION

The following description is provided to assist in understanding the teachings disclosed herein and will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

The present disclosure is directed to a photocurable composition comprising a photoinitiator and a polymerizable material, wherein the polymerizable material can comprise a first polymerizable monomer having a structure of Formula (1) or Formula (2):

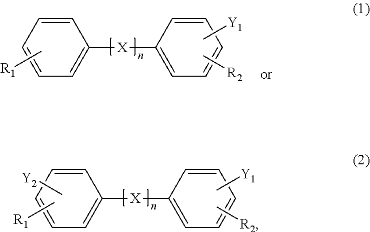

with X being C₁-C₄-alkyl or oxygen (O); n being 0 or 1; Y₁, Y₂ being

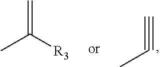

with R₃ being H or methyl, wherein Y₁ and Y₂ may be the same or different and an amount of Y₁ and Y₂ per benzene ring being 1, 2, or 3; R₁, R₂ being substituted or unsubstituted alkyl or aryl, and an amount of each of R₁ and R₂ per benzene ring being 0, 1, 2, 3, or 4. As used herein, if not indicated otherwise, the term “first polymerizable monomer” relates to a monomer having the structure of Formula (1) or (2).

In one embodiment, the amount of the first polymerizable monomer can be at least 5 wt % based on the total weight of the polymerizable material, or at least 10 wt %, or at least 15 wt %, or at least 20 wt %, or at least 30 wt %. In another aspect, the amount of the first polymerizable monomer may not be greater than 50 wt %, or not greater than 45 wt %, or not greater than 40 wt %, or not greater than 35 wt %, or not greater than 30 wt %, or not greater than 25 wt % based on the total weight of the polymerizable material.

In certain embodiments, the first polymerizable monomer can have a structure as shown in Formulas (3), (4), (5), and (6):

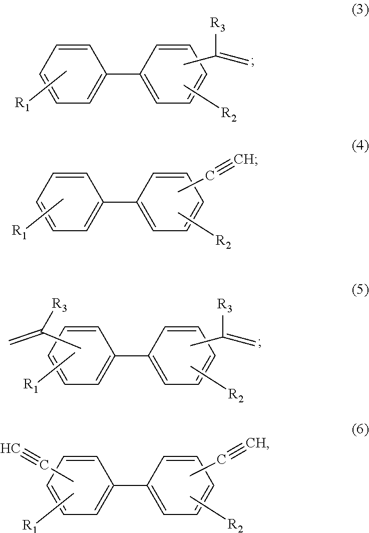

wherein R₃ is H or methyl, R₁ and R₂ are one or more alkyl, aryl, or alkyl aryl and may be the same or different, an amount of each of R₁ and R₂ per benzene ring being 0, 1, 2, 3, or 4, an amount of

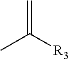

per benzene ring being 1 or 2, and an amount of or

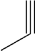

per benzene ring being 1 or 2. In certain aspects, R₁ and R₂ can be independently one or more C₁-C₅ alkyl.

In other embodiments, the first polymerizable monomer can have a structure as shown in Formulas (7), (8), (9), and (10):

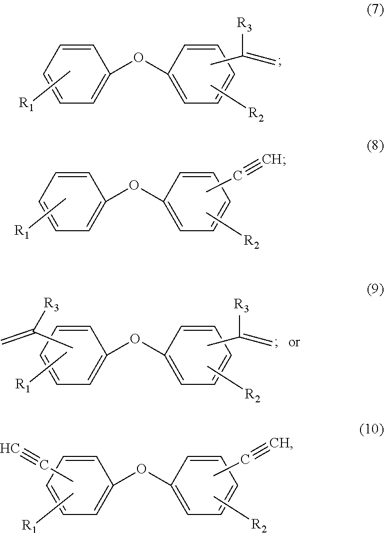

wherein R₃ is H or methyl, and R₁ and R₂ are one or more alkyl, aryl, or alkyl aryl and may be the same or different, an amount of each of R₁ and R₂ per benzene ring being 0, 1, 2, 3, or 4, an amount of

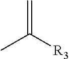

per benzene ring being 1 or 2, and an amount of or

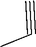

per benzene ring being 1 or 2. In certain aspects, R₁ and R₂ can be independently one or more C₁-C₅ alkyl.

In certain particular aspects, the first polymerizable monomer may have one of the following structures (11), (12), (13), (14), (15), (16) or (17):

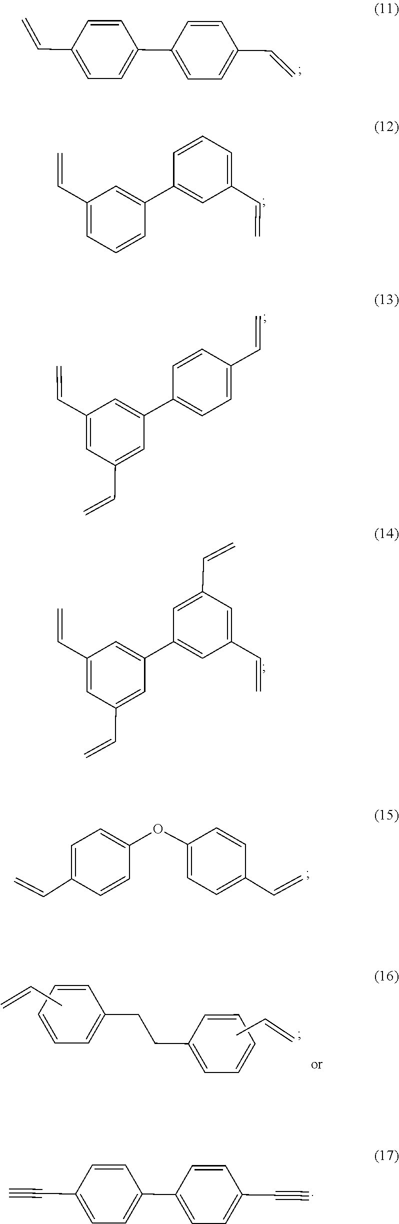

The at least one monomer falling under Formula (1) and (2) can have the advantage of a high carbon content, which may contribute to a high final carbon content in the formed photo-cured layer. In one aspect, the carbon content of the at least one first monomer can be at least 80% based on the total weight of the first monomer, or at least 85%, or at least 90%, or at least 92%, or at least 93%, or at least 94%.

In another aspect, the at least one first monomer can have a vapor pressure of not greater than 0.01 mmHg, or not greater than 0.005 mmHg, or not greater than 0.001 mmHg, or not greater than 0.0005 mmHg, or not greater than 0.0003 mmHg, at a temperature of 25° C.

In a certain particular embodiment, the at least one first monomer can have a carbon content of at least 92% based on the total weight of the at least one monomer and a vapor pressure of not greater than 0.001 mmHg.

In a further embodiment, the polymerizable material of the photocurable composition can comprise at least one second monomer which does not fall under Formula (1) or Formula (2) of the at least one first monomer.

In one aspect, the at least one second monomer can include at least one acrylate monomer, such as two acrylate monomers, three acrylate monomers, four acrylate monomers, or five acrylate monomers. As used herein, the term “acrylate” means unsubstituted acrylate or alkyl-acrylate, for example, methacrylate. In certain aspects, the acrylate monomer can be at least one mono-functional acrylate monomer, at least one multi-functional acrylate monomers, or a combination thereof.

In another aspect, the at least one second monomer can be a mono-functional monomer or a multi-functional monomer. In a certain aspect, the at least one second monomer of the polymerizable material can include at least one di-functional acrylate monomer or at least one tri-functional acrylate monomer. In a further aspect, the second monomer may include a non-acrylic monomer, for example, a mono-functional or multi-functional vinylbenzene compound. In a certain particular aspect, the vinylbenzene compound can be divinylbenzene.

The amount of polymerizable material in the photocurable composition can be at least 30 wt % based on the total weight of the photocurable composition, such as at least 50 wt %, at least 60 wt %, at least 70 wt %, at least 80 wt %, at least 85 wt %, at least 90 wt %, or at least 95 wt %. In another aspect, the amount of polymerizable material may be not greater than 99 wt %, such as not greater than 98 wt %, or not greater than 97 wt %, or not greater than 95 wt % based on the total weight of the photocurable composition. The amount of polymerizable material can be a value between any of the minimum and maximum values noted above. In a particular aspect, the amount of the polymerizable material can be at least 80 wt % and not greater than 98 wt %.

In another embodiment, the polymerizable material of the photocurable composition can include a certain amount of polymerizable monomers, oligomers, or polymers in addition to the at least one first polymerizable monomer and one second polymerizable monomer.

In one aspect, the viscosity of the photo-curable composition can be not greater than 50 mPa·s, such as not greater than 40 mPa-s, not greater than 30 mPa·s, not greater than 25 mPa·s, not greater than 20 mPa-s, not greater than 15 mPa-s, or not greater than 10 mPa·s. In another aspect, the viscosity may be at least 2 mPa·s. or at least 3 mPa-s, or at least 5 mPa-s. As used herein, all viscosity values relate to viscosities measured at a temperature of 23° C. with the Brookfield method using a Brookfield Viscometer.

The photocurable composition can be adapted that a photo-cured layer formed from the photocurable composition may have a high thermal stability. In one aspect, an onset temperature for the thermal degradation of the of the photo-cured layer may be greater than 250° C., or greater than 300° C., or greater than 350° C., or greater than 375° C., or greater than 400° C. As used herein, the onset thermal degradation temperature is also called “thermal degradation temperature,” and relates to the temperature in the TGA curve wherein a deflection of the curve from the almost linear plateau is first observed, shortly before the steep degradation decline of the sample.

In one embodiment, the first photocurable composition of the present disclosure can be essentially free of a solvent. As used herein, if not indicated otherwise, the term solvent relates to a compound that can dissolve or disperse the polymerizable monomers but does not itself polymerize during the photo-curing of the photocurable composition. The term “essentially free of a solvent” means herein an amount of solvent being not greater than 5 wt % based on the total weight of the photocurable composition. In a certain particular aspect, the amount of the solvent can be not greater than 3 wt %, not greater than 2 wt %, not greater than 1 wt %, or the photocurable composition can be free of a solvent, except for unavoidable impurities.

In another particular aspect, the photocurable composition can include a solvent in an amount of at least 6 wt % based on the total weight of the photocurable composition, or at least 8 wt %, at least 10 wt %, at least 15 wt %, at least 20 wt %, at least 30 wt %, or at least 50 wt %. In another aspect, the amount of solvent may be not greater than 80 wt %, or not greater than 50 wt %, or not greater than 40 wt %, or not greater than 30 wt %, or not greater than 20 wt %, or not greater than 15 wt %.

In order to initiate the photo-curing of the composition if exposed to light, one or more photoinitiators can be included in the photocurable composition.

In a certain aspect, the curing can be also conducted by a combination of light and heat curing.

The photocurable composition can further contain one or more optional additives. Non-limiting examples of optional additives can be stabilizers, dispersants, solvents, surfactants, inhibitors, or any combination thereof.

The photocurable composition of the present disclosure can be adapted for use in inkjet adaptive planarization (IAP) or in nanoimprint lithography (NIL).

In one embodiment, the photocurable composition can be applied on a substrate to form a photo-cured layer. As used herein, the combination of substrate and photo-cured layer overlying the substrate is called a laminate.

The inclusion of the at least one first monomer of the polymerizable material can contribute to a high carbon content in the formed photo-cured layer. In one embodiment, the photocurable composition can be adapted that a carbon content of the photo-cured layer may be at least 70%, or at least 71%, at least 72%, at least 73%, at least 74%, or at least 75%. As used herein, the carbon content of the photo-cured layers can be determined by elemental analysis using standard commercial analytical measurement techniques.

In another aspect, the photo-cured layer of the laminate can have an Ohnishi number of not greater than 3.2, or not greater than 3.0, or not greater than 2.9, or not greater than 2.8, or not greater than 2.7, or not greater than 2.6. In another aspect, the Ohnishi number may be at least 1.8, such as at least 1.9, at least 2.0, at least 2.1, at least 2.2, or at least 2.3.

In a particular embodiment, the photo-cured layer can have a carbon content of at least 70% and an Ohnishi number of not greater than 2.9.

The present disclosure is further directed to a method of forming a photo-cured layer. The method can comprise applying a layer of the photocurable composition described above over a substrate, bringing the photocurable composition into contact with a template or superstrate; irradiating the photocurable composition with light to form a photo-cured layer; and removing the template or the superstrate from the photo-cured layer.

The substrate and the solidified layer may be subjected to additional processing, for example, an etching process, to transfer an image into the substrate that corresponds to the pattern in one or both of the solidified layers and/or patterned layers that are underneath the solidified layer. The substrate can be further subjected to known steps and processes for device (article) fabrication, including, for example, curing, oxidation, layer formation, deposition, doping, planarization, etching, formable material removal, dicing, bonding, and packaging, and the like.

The photo-cured layer may be further used as an interlayer insulating film of a semiconductor device, such as LSI, system LSI, DRAM, SDRAM, RDRAM, or D-RDRAM, or as a resist film used in a semiconductor manufacturing process.

As further demonstrated in the examples, monomers falling under the chemical structure of Formula (1) or (2) can have the advantage of a high carbon content, a low vapor pressure, and a low viscosity, thereby making them suitable to be included in photocurable compositions adapted for IAP or NIL processing. The photocurable compositions can be used for forming photo-cured layers with only minor loss of monomers due to evaporation, leading to photo-cured layers having a homogeneous structure, a high etch resistance, and high thermal stability.

### EXAMPLES

The following non-limiting examples illustrate the concepts as described herein.

### Example 1

Comparison of Properties of Examples of the First Polymer

Table 1 includes representative monomers (11-17) all falling under the structure of Formulas (1) and (2), together with the calculated carbon content and calculated vapor pressure. It can be seen that the carbon content of the listed monomers 11-17 is greater than about 86%. If the two phenyl groups are directly connected, the carbon content is greater than 92%.

Furthermore, the calculated vapor pressures for monomers 11-17 is not greater than 0.0005 mmHg.

In contrast, benzyl acrylate (BA) and divinylbenzol (DVB), typical monomers for use in resist compositions in IAP and NIL processing, have not such a combination of high carbon content and low vapor pressure. Both DVB and BA have much higher vapor pressures; in addition, BA has a much lower carbon content.

TABLE 1

| | | | Vapor |
|---|---|---|---|
| Monomer | | Carbon | pressure |
| Formula # | Structure | Content [%] | [mmHg] |
| 11 | 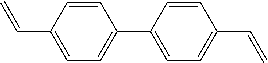 [SMILES: C=Cc1ccc(-c2ccc(C=C)cc2)cc1] | 93.08 | 1.57E−04 |
| 12 | 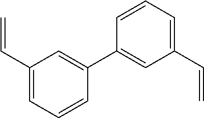 [SMILES: C=Cc1cccc(-c2cccc(C=C)c2)c1] | 93.08 | 4.44E−05 |
| 13 | 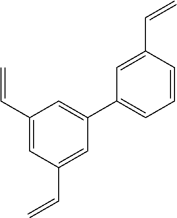 [SMILES: C=Cc1cccc(-c2cc(C=C)cc(C=C)c2)c1] | 92.98 | 2.27E−06 |
| 14 | 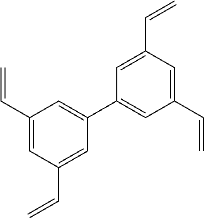 [SMILES: C=Cc1cc(C=C)cc(-c2cc(C=C)cc(C=C)c2)c1] | 92.93 | 3.88E−06 |
| 15 | 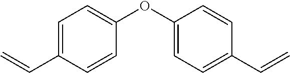 [SMILES: C=Cc1ccc(Oc2ccc(C=C)cc2)cc1] | 86.38 | 1.80E−04 |
| 16 | 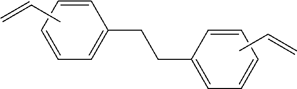 | 92.17 | 1.27E−04 |
| 17 | 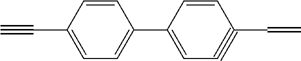 | 94.93 | 6.83E−04 |

Photocurable Compositions

A series of photocurable compositions was prepared including varying amounts of the monomers shown in Table 1. A summary of ingredients of the polymerizable material is shown in Tables 2 and 3.

TABLE 2

| Ingredient | S1 | S2 | S3 | C1 | S4 | S5 | S6 | S7 | S8 | C2 |
|---|---|---|---|---|---|---|---|---|---|---|
| Diacrylate-A | 90 | 70 | 70 | 100 | | | | | | |
| Diacrylate-C | | | | | 90 | 90 | 90 | 70 | 60 | 100 |
| Triacrylate-B | | | | | | | | | | |
| Vinyl- | | | | | | | | | | |
| acrylate | | | | | | | | | | |
| 2-VBPH | 10 | 30 | 17 | | 10 | | | 30 | 30 | |
| 3VPH | | | | | | 10 | | | | |
| 4VPH | | | | | | | 10 | | | |
| DVPE | | | 13 | | | | | | 10 | |
| BVPE | | | | | | | | | | |
| Viscosity | 11.4 | 11.9 | 11.7 | 10.80 | 17.3 | 18.8 | 20.3 | 16.7 | 16.3 | 17.55 |
| Carbon | 71 | 76 | 75 | 68 | 73 | 73 | 73 | 77 | 79 | 71 |
| Content | | | | | | | | | | |
| T(X) | | | | 332 | | | | | | 354 |

TABLE 3

| Ingredient | S9 | S10 | S11 | S12 | S13 | C3 | S16 | S17 | S18 | C4 |
|---|---|---|---|---|---|---|---|---|---|---|
| Diacrylate-A | | | | | | | 90 | 87 | | |
| Diacrylate C | | | | | | | | | | |
| Triacrylate-B | | | | | | | | | 90 | 100 |
| Vinylacrylate | 90 | 80 | 70 | 70 | 60 | 100 | | | | |
| 2-VBPH | 10 | 20 | 30 | | 30 | | | | | |
| 3VPH | | | | | | | | | | |
| 4VPH | | | | | | | | | | |
| DVPE | | | | | 10 | | 10 | 13 | 10 | |
| BVPE | | | | 30 | | | | | | |
| Viscosity | 8.2 | 8.7 | 9.3 | 8.3 | 9.8 | 7.67 | 11.53 | 11.53 | 47.66 | 58.5 |
| Carbon | 80 | 81 | 83 | 83 | 84 | 78 | 70 | 71 | 63 | 61 |
| Content [%] | | | | | | | | | | |
| T(X) | | | | | | 355 | 362 | 368 | 382 | 360 |

All photocurable compositions contained next to the polymerizable material 1 wt % surfactant and 2 wt % photo initiator. Diacrylate A was m-xylylene diacrylate, diacrylate C was 5-ethenyl-1,3-benylacrylate, and triacrylate B was trimethylolpropane triacrylate.

It can be seen from Tables 2 and 3 that already the presence of small amounts of monomers described herein as “at least one first polymerizable monomer”, which fall under the general structures of Formula (1) or Formula (2), can lead to an increase in the calculated carbon content of the polymerizable material by 2 or more percent. The carbon content of the polymerizable material was calculated based on the known molecular weights and amounts of the monomers of the polymerizable material. It could further be observed that the addition of the monomers falling under Formula (1) and (2) had no detrimental effect on the viscosities, which means no unwanted increase in viscosity to values above 50 mPa s at 23° C.

It could be further observed that photo-cured layers made from the photocurable composition may have an increased thermal degradation temperature in comparison to photo-cured layers formed from the respective photocurable compositions not including one of the monomers 11-17 listed in Table 1.

The photo-cured layers were prepared by adding the respective resist composition between two glass slides, the two glass slides having a distance of 300 microns to each other. The resist between the glass slides was photo-cured by applying a radiation energy of 2.4 J. The photo-cured layers were analyzed via thermographical analysis (TGA). The TGA was conducted using a LINSEIS STA PT1000 instrument (Linseis Messgeraete GmbH, Germany). All measurements were conducted under nitrogen at a rate of 5 liters per hour. The samples (about 25 mg per test) were heated at a rate of 20° C./minute and the loss of weight was continually recorded.

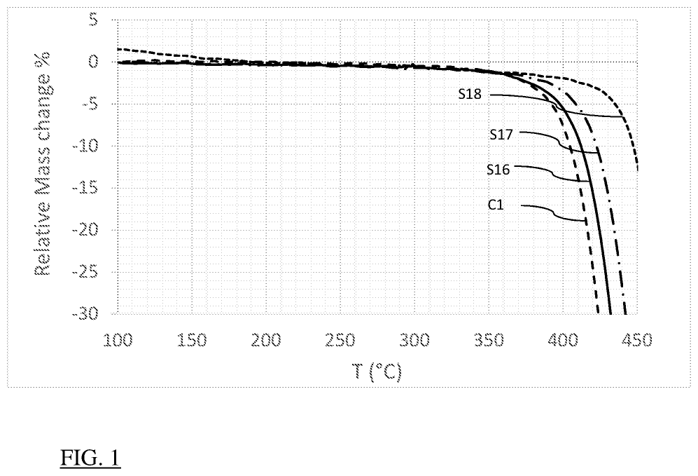

The TGA curves of the materials of some representative photo-cured layers (S16, S17, and S18) and comparative photo-cured layer C1 are shown in FIG. 1. It can be seen that all the shown analyzed materials had a degradation temperature greater than 350° C., except C1. It can be further seen that the addition of minor amounts of the biphenyl-monomer of the present disclosure can increase the thermal degradation temperature of the material. For example, an amount of 10 wt % of monomer 16 (sample S16) could increase the thermal degradation temperature of respective composition C1 (only containing diacrylate-A) by about 30° C.

As used herein, the thermal degradation temperature relates to the initial degradation temperature T(X), which is the temperature of the TGA curve wherein a deflection of the curve from the almost linear plateau shape is first observed, shortly before the steep decline of the mass of the sample, i.e., degradation.

Measurement of the Viscosities

The viscosities for samples C1-C4 and S16-S18 were measured with a Brookfield DV-11+Pro viscometer using spindle #18. For each viscosity measurement, a sample of 6-7 ml was taken, added to the sample chamber, and allowed to equilibrate for 15-20 minutes to reach the target temperature of 23° C. The viscosities were measured with spindle #18 at a speed of 135 rpm. For each sample, the measurement was three times repeated and an average value calculated.

The viscosities for samples S1-S13 were calculated according to the following equation:

$$Ln ( μ / ρ + a ) = EXP ( wi ( b Ln ( \frac{Ln μ i}{ρ i} + a ) + c ) - c ) / b ) ,$$

with μ being the viscosity, ρ being the density, μi, ρi, wi being viscosity, density, and mass fraction of each component; a, b, and c were determined beforehand being: a=0.8, b=14,534, and c=10.975. This calculation method is described, for example, in Schmirler et al., AIP Conference Proceedings 1889, 020035 (2017).

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A photocurable composition comprising a polymerizable material and a photoinitiator, wherein the polymerizable material comprises a first polymerizable monomer having a structure of Formula (1) or Formula (2): 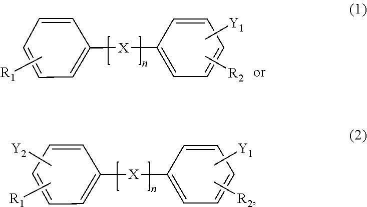
with
X being C₁-C₄-alkyl or oxygen (O); n being 0 or 1
Y₁, Y₂ being 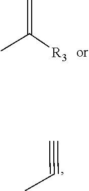
with R₃ being H or methyl, wherein Y₁ and Y₂ being the same or different and an amount of Y₁ and Y₂ per benzene ring being 1, 2, or 3;
R₁, R₂ being substituted or unsubstituted alkyl or aryl, and an amount of each of R₁ and R₂ per benzene ring being 0, 1, 2, 3, or 4.

2. The photocurable composition of claim 1, wherein the first polymerizable monomer includes a structure selected from Formula (3), (4), (5), or (6): 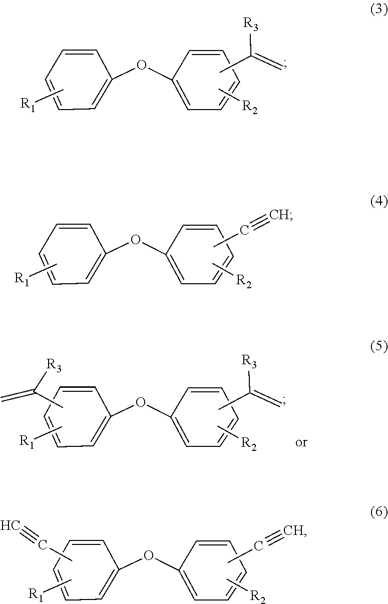
wherein R₃ is H or methyl, and R₁ and R₂ are one or more alkyl, aryl, or alkyl aryl and may be the same or different, an amount of each of R₁ and R₂ per benzene ring being 0, 1, 2, 3, or 4, an amount of 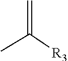
per benzene ring being 1 or 2, and an amount of or 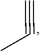
per benzene ring being 1 or 2.

3. The photocurable composition of claim 1, wherein the first polymerizable monomer includes a structure selected from Formula (7), (8), (9), or (10): 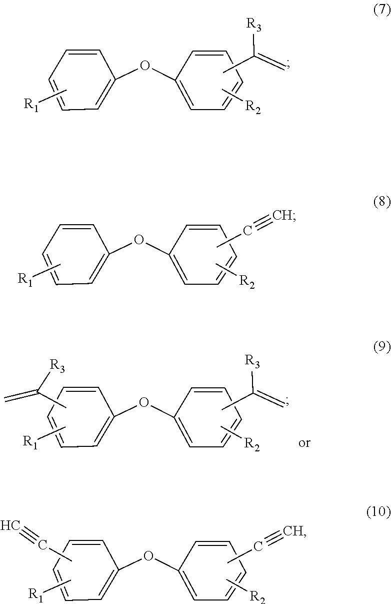
wherein R₃ is H or methyl, and R₁ and R₂ are one or more alkyl, aryl, or alkyl aryl and may be the same or different, an amount of each of R₁ and R₂ per benzene ring being 0, 1, 2, 3, or 4, and an amount of 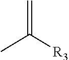
per benzene ring being 1 or 2, and an amount of or 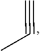
per benzene ring being 1 or 2.

4. The photocurable composition of claim 1, wherein the first polymerizable monomer is at least one monomer selected from the following structures:

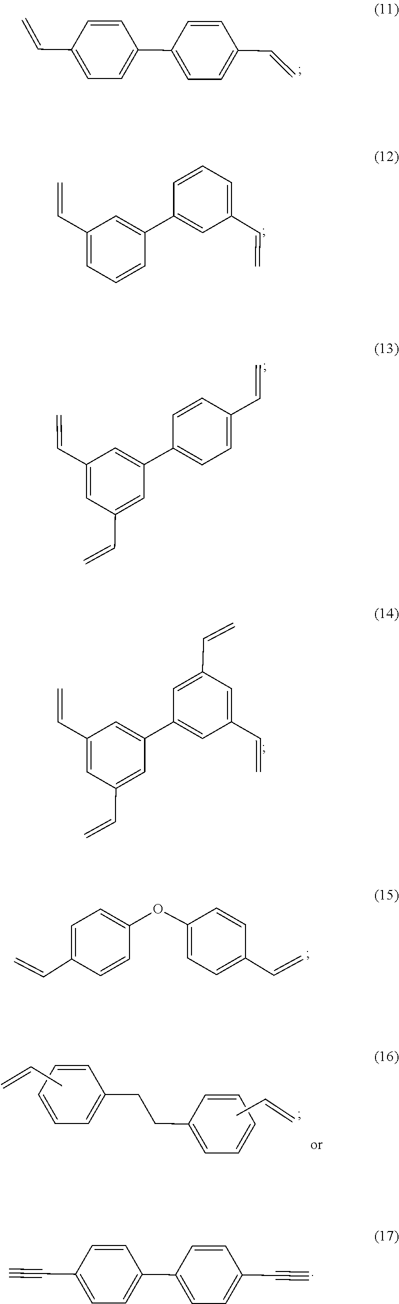

5. The photocurable composition of claim 1, wherein the polymerizable material comprises at least one second monomer, the at least one second monomer including at least one acrylate monomer.

6. The photocurable composition of claim 5, wherein the at least one acrylate monomer includes at least two mono-functional acrylate monomers.

7. The photocurable composition of claim 5, wherein the at least one acrylate monomer comprises at least one mono-functional acrylate monomer and at least one multi-functional acrylate monomer.

8. The photocurable composition of claim 1, wherein an amount of the polymerizable material is at least 80 wt % based on the total weight of the photocurable composition.

9. The photocurable composition of claim 1, wherein a viscosity at 23° C. of the photocurable composition is not greater than 50 mPa s.

10. The photocurable composition of claim 1, wherein the photocurable composition comprises a solvent in an amount of at least 15 vol % based on the total volume of the photocurable composition.

11. The photocurable composition of claim 1, wherein the photocurable composition is essentially free of a solvent.

12. The photocurable composition of claim 1, wherein an amount of the first monomer is at least 5 wt % and not greater than 50 wt % based on the total weight of the photocurable composition.

13. The photocurable composition of claim 12, wherein the amount of the first monomer is at least 30 wt % based on the total weight of the polymerizable material.

14. The photocurable composition of claim 1, wherein the composition is adapted for use in inkjet adaptive planarization (IAP) or nanoimprint lithography (NIL).

15. A laminate comprising a substrate and a photo-cured layer overlying the substrate, wherein the photo-cured layer is formed from the photocurable composition of claim 1.

16. The laminate of claim 15, wherein the photo-cured layer has a carbon content of at least 70%.

17. The laminate of claim 15, wherein the photo-cured layer has a thermal stability of at least 250° C.

18. A method of forming a photo-cured layer on a substrate, comprising:
applying a layer of a photocurable composition on the substrate, wherein the photocurable composition comprises a photoinitiator and a polymerizable material, the polymerizable material including a first polymerizable monomer having a structure of Formula (1) or Formula (2): 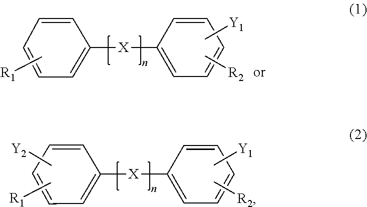
with
X being C₁-C₄-alkyl or oxygen (O); n being 0 or 1
Y₁, Y₂ being 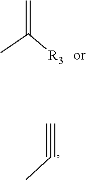
with R₃ being H or methyl, wherein Y₁ and Y₂ may be the same or different and an amount of Y₁ and Y₂ per benzene ring being 1, 2, or 3;
R₁, R₂ being substituted or unsubstituted alkyl or aryl, and an amount of each of
R₁ and R₂ per benzene ring being 0, 1, 2, 3, or 4;
bringing the photocurable composition into contact with a template or a superstrate;
irradiating the photocurable composition with light to form a photo-cured layer;
and removing the template or the superstrate from the photo-cured layer.

19. The method of claim 18, wherein the first polymerizable monomer comprises at least one second monomer, the at least one second monomer including at least one acrylate monomer.

20. A method of forming an article, comprising:
applying a layer of a photocurable composition on the substrate, wherein the photocurable composition comprises a photoinitiator and a polymerizable material, the polymerizable material including a first polymerizable monomer having a structure of Formula (1) or Formula (2): 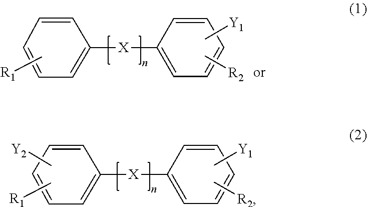
with
X being C₁-C₄-alkyl or oxygen (O); n being 0 or 1
Y₁, Y₂ being 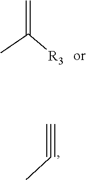
with R₃ being H or methyl, wherein Y₁ and Y₂ may be the same or different and an amount of Y₁ and Y₂ per benzene ring being 1, 2, or 3;
R₁, R₂ being substituted or unsubstituted alkyl or aryl, and an amount of each of
R₁ and R₂ per benzene ring being 0, 1, 2, 3, or 4;
bringing the photocurable composition into contact with a template or a superstrate;
irradiating the curable composition with light to form a cured layer;
removing the template or the superstrate from the photo-cured layer;
forming a pattern on the substrate;
processing the substrate on which the pattern has been formed in the forming; and
manufacturing an article from the substrate processed in the processing.
